(19) United States
(12) Patent Application Publication
(10) Pub. No.: US 2024/0006258 A1
(43) Pub. Date: Jan. 4, 2024

(54) SUBSTRATES WITH NITRIDED GLASS CORES

(71) Applicant: Intel Corporation, Santa Clara, CA (US)

(72) Inventors: Suddhasattwa Nad, Chandler, AZ (US); Darko Grujicic, Chandler, AZ (US); Rengarajan Shanmugam, Chandler, AZ (US)

(73) Assignee: Intel Corporation, Santa Clara, CA (US)

(21) Appl. No.: 17/856,969

(22) Filed: Jul. 2, 2022

(51) Int. Cl. H01L 23/15; H01L 23/498; H01L 21/48

(52) U.S. Cl. CPC H01L 23/15; H01L 23/49866; H01L 23/49833; H01L 23/49822; H01L 21/4857; H01L 21/486; H01L 23/49816; H01L 24/16

(57) ABSTRACT

Substrates with nitrided glass cores, and methods of forming the same, are described herein. In one example, a substrate includes one or more glass layers and a plurality of dielectric layers. At least one of the glass layers includes nitrogen. Further, at least one of the dielectric layers is above the one or more glass layers and at least one of the dielectric layers is below the one or more glass layers.

### BACKGROUND

Copper-clad laminates (CCLs) are commonly used as the core in semiconductor substrates, such as package substrates and printed circuit boards (PCBs). However, glass cores are a promising alternative that can provide various advantages over CCLs. One challenge with glass cores, however, is that glass does not always bond well with subsequent functional layers. As a result, metallization of glass cores may require intervening adhesive layers to be formed between the glass core and the subsequent functional layers.

### BRIEF DESCRIPTION OF THE DRAWINGS

FIG. 1 illustrates a cross-section view of a substrate with a surface-nitrided glass core in accordance with certain embodiments.

FIGS. 2A-E illustrate cross-section views of a surface-nitrided glass core substrate during various stages of fabrication.

FIG. 3 illustrates a cross-section view of a substrate with a nitrided glass core in accordance with certain embodiments.

FIGS. 4A-D illustrate cross-section views of a nitrided glass core substrate during various stages of fabrication.

FIG. 5 illustrates a cross-section view of an electronic device in accordance with certain embodiments.

FIG. 6 illustrates a flowchart for forming an integrated circuit package on a nitride glass core substrate in accordance with certain embodiments.

FIG. 7 is a top view of a wafer and dies that may be included in a microelectronic assembly, in accordance with any of the embodiments disclosed herein.

FIG. 8 is a cross-sectional side view of an integrated circuit device that may be included in a microelectronic assembly, in accordance with any of the embodiments disclosed herein.

FIG. 9 is a cross-sectional side view of an integrated circuit device assembly that may include a microelectronic assembly, in accordance with any of the embodiments disclosed herein.

FIG. 10 is a block diagram of an example electrical device that may include a microelectronic assembly, in accordance with any of the embodiments disclosed herein.

### DETAILED DESCRIPTION

Copper-clad laminates (CCLs) are commonly used as the core in semiconductor substrates, such as package substrates and printed circuit boards (PCBs). However, glass cores are a promising alternative that can provide various advantages over CCLs, such as low total thickness variation (TTV), low coefficient of thermal expansion (CTE), low shrinkage, and high modulus.

One challenge with glass cores, however, is that glass may not bond well with subsequent functional layers, such as dielectric buffer layers and conductive seed layers that are formed on the glass core. As a result, metallization of glass cores may require the application of intervening adhesive layers between the glass core and the subsequent functional layers. This typically requires creating electrically non-functional buffer layers—exclusively for adhesive purposes—using an expensive and slow film deposition process.

Accordingly, this disclosure presents embodiments of substrates with nitrided glass cores, and methods of forming the same. In these embodiments, rather than forming additional adhesive layers on a glass core, the glass core is nitridized directly to form a nitrided glass interface, which improves adhesion to subsequent dielectric/conductive layers, eliminates the need for non-functional adhesive layers, and improves overall program affordability. For example, after the glass core is nitridized, subsequent dielectric layers can be directly laminated on the glass core, eliminating the need for non-functional adhesive layers while retaining their adhesive properties.

These embodiments provide various advantages, including improved adhesion on glass cores without requiring intervening adhesive layers to be formed on the cores, which simplifies the fabrication process, reduces tool counts, and lowers costs.

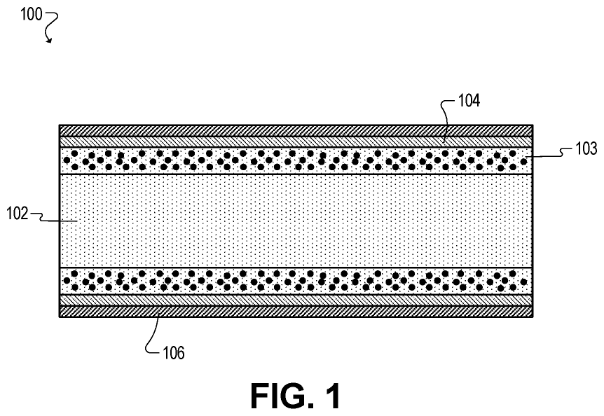

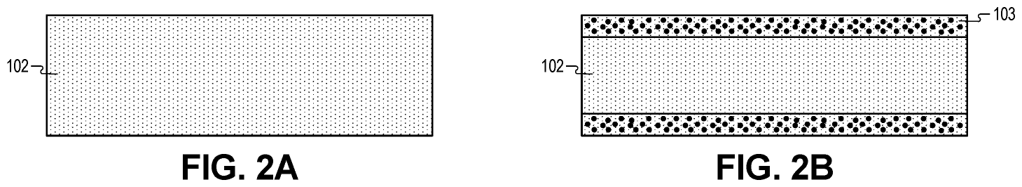

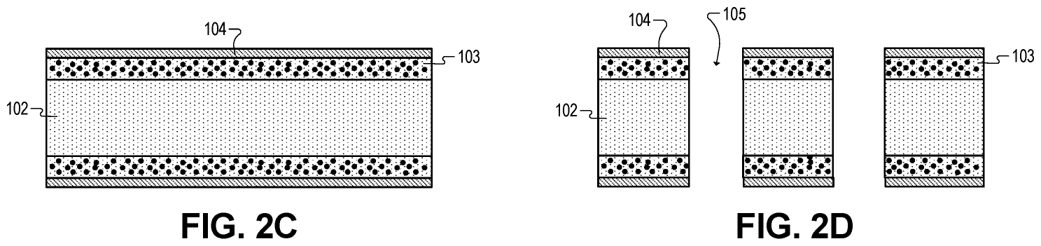

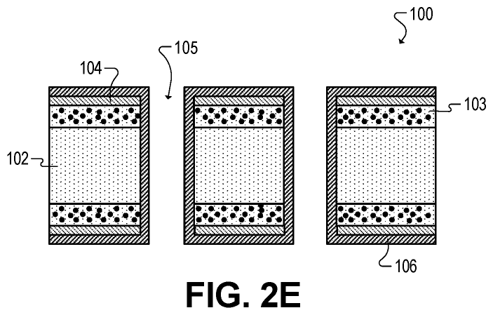

FIG. 1 illustrates a cross-section view of a substrate 100 with a surface-nitrided glass core in accordance with certain embodiments. In the illustrated embodiment, substrate 100 includes a glass core 102 with nitrided glass surfaces 103, a dielectric laminate 104, and a conductive seed layer 106. The nitrided glass surfaces 103 of the core 102 provide strong adhesive properties, which enables subsequent layers, such as the dielectric layers 104, to bond or stick to the glass core 102 without requiring additional intervening adhesive layers to be formed on the core. In some embodiments, however, additional intervening layers may still be included, whether for adhesion or other purposes. The process of forming surface-nitrided glass core substrate 100 is described in further detail in connection with FIGS. 2A-E.

FIGS. 2A-E illustrate cross-section views of a surface-nitrided glass core substrate 100 during various stages of fabrication. In the illustrated example, the surface-nitrided glass core substrate 100 of FIG. 1 is fabricated using surface nitridation techniques to nitridize the surface of a glass core.

In FIG. 2A, a glass core 102 for the substrate is formed, or alternatively, a pre-formed glass core 102 is provided (e.g., from a glass or substrate manufacturer). In some embodiments, the glass core 102 may include one or more layers of glass, potentially along with one or more dielectric or adhesive layers bonding the glass layers together (not shown).

In FIG. 2B, the surfaces of the glass core 102 are nitridized to create a surface-nitrided glass core. The surface nitridation causes the top and bottom surfaces of the glass core 102 to become nitrided glass layers 103. Accordingly, the resulting core structure includes the glass core 102 and nitrided glass layers 103 above and below the glass core 102, as shown in FIG. 2B. In this manner, the nitrided glass surface provides better adhesion and enables subsequent layers (e.g., dielectric layers 104) to bond to the glass core with or without any other intervening adhesive layers.

In some embodiments, this may be accomplished by nitriding the surface of the glass core using a high-temperature ammonia plasma treatment, pressurized nitrogen and/or ammonia chemical treatment, and so forth. For example, nitriding is a treating process that diffuses nitrogen into the surface of another material. In some cases, the resulting material may have superior properties, such as adhesion, surface hardness/strength, and so forth. There are a variety of nitriding methods and treatments that can be used to nitridize glass, including, but not limited to, gas nitriding, plasma nitriding, pressurized nitrogen treatments, and salt bath nitriding. In some cases, these nitriding treatments may be performed by glass manufacturers and/or substrate manufacturers.

In gas nitriding, a heat treatment is performed using a nitrogen-rich gas, such as ammonia (NH₃). For example, when ammonia comes into contact with heated glass, it dissociates into nitrogen and hydrogen. The nitrogen then diffuses onto the surface of the glass, which creates a nitrided glass layer. The thickness and phase constitution of the resulting nitrided layers can be selected/tuned and the nitriding process can be optimized to achieve the desired properties.

In plasma nitriding, also known as ion nitriding, the nitriding reaction is caused by the ionized state of the gas rather than the temperature. For example, plasma nitriding uses intense electric fields to generate ionized molecules of the gas around the surface to be nitrided. This highly active gas with ionized molecules is referred to as plasma. Since nitrogen reactive species (e.g., ions, radicals, etc.) are made available by ionization, plasma nitriding efficiency does not depend on the temperature. As a result, plasma nitriding can be performed at a broad range of temperatures (e.g., from 260° C. to more than 600° C.). Plasma nitriding is typically performed using pure nitrogen gas (N₂) or ammonia (NH₃).

In general, any suitable nitrogen gas can be used for gas and plasma nitriding, including, but not limited to, pure nitrogen (N₂), ammonia (NH₃), ammonium hydroxide (NH₄OH), nitric oxide (NO), azanide (NH₂), gaseous mixtures of ammonia with water (H₂O) and/or hydrogen chloride (HCl), and other nitrogen/hydrogen/oxygen containing groups. Pressurized nitrogen treatments can also be used, either alone or in conjunction with gas and plasma nitriding.

In salt bath nitriding, a nitrogen-containing salt (e.g., cyanide salt) and the glass are both heated, and the glass is submerged in the salt for a certain amount of time.

Any other suitable nitriding treatments may also be used, either separately or in conjunction with the foregoing techniques.

In FIG. 2C, the surfaces of the substrate core are laminated with a dielectric film. As a result, dielectric layers 104 are formed above and below the nitrided glass layers 103. The dielectric layers 104 may be formed using any suitable dielectric material or film, including, but not limited to, an organic material, resin, epoxy, polyimide, polyester, or other polymer, combination of polymers, or polymer composites. In some embodiments, the dielectric layers 104 may be formed using Ajinomoto Build-up Film (ABF). Besides lamination, the dielectric film can also be fabricated using coating/slurry-based methods.

In FIG. 2D, through holes 105 are formed through the substrate core. The through holes 105 may be formed using any suitable method or combination of methods, such as etching, laser drilling, imprinting, sand blasting, and so forth. Moreover, the through holes 105 may be used to form vias in subsequent metallization steps (not shown). For example, as described below, the through holes 105 may be subsequently filled with metal or another conductive material to form through-hole vias for interconnects patterned on the substrate core.

In FIG. 2E, exposed surfaces of the substrate core are deposited or laminated with a conductive material. As a result, conductive layers 106 are formed on the top and bottom surfaces of the substrate core 100 (e.g., above and below the dielectric layers 104) and on the walls of the through holes 105. In some embodiments, the conductive layers 106 serve as seed layers for additional metal layers that are formed during subsequent metallization steps (not shown). For example, the conductive seed layers 106 (or a portion of which) may serve as an adhesive that bonds the subsequent metal layers to the dielectric layers 104 (and/or glass layers 102, 103) on the substrate core 100. The conductive seed layers 106 may be formed using any suitable metal or other conductive material, including, but not limited to, titanium, copper, chromium, nickel, ruthenium, cobalt, tantalum or vanadium, as well as alloys of these and/or other metals. Nitrided versions of these seed layers could also be employed (e.g., titanium nitride, tantalum nitride).

At this point, the surface-nitrided glass core substrate 100 may be complete. However, as noted above, subsequent metallization processing may be performed to pattern conductive traces (e.g., interconnects) on the substrate 100. For example, conductive traces may be patterned by forming vias through the core (e.g., by filling the through holes 105 with metal), forming a series of dielectric (e.g., buildup) layers and conductive layers above and/or below the core (e.g., where conductive layers are separated by dielectric layers), forming vias through dielectric layers to interconnect conductive layers (e.g., through hole vias, blind vias, buried vias), forming conductive contacts on the substrate surface (e.g., solder balls/bumps, metal pads), and so forth.

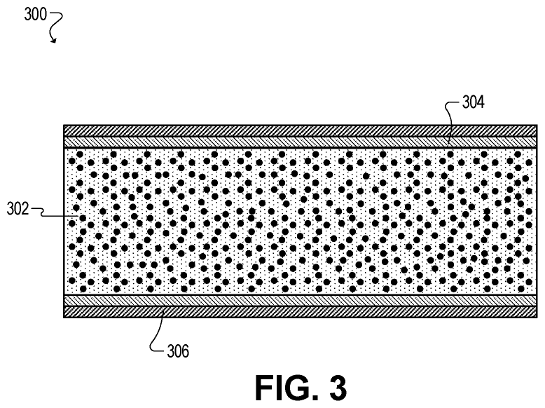

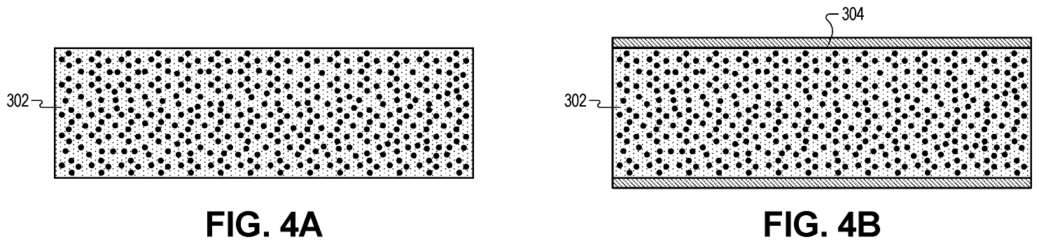

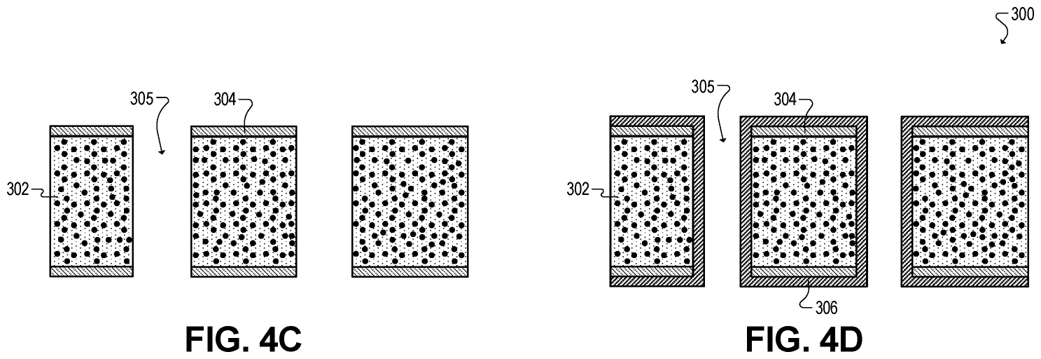

FIG. 3 illustrates a cross-section view of a substrate 300 with a fully-nitrided glass core in accordance with certain embodiments. In the illustrated embodiment, substrate 300 includes a fully-nitrided glass core 302, a dielectric laminate 304, and a conductive seed laminate 306. By way of comparison, while surface-nitrided glass core 102 has nitrided glass surfaces, fully-nitrided glass core 302 contains nitrided glass throughout its entirety. The nitrided glass in the core 302 provides strong adhesive properties, which enables subsequent layers, such as the dielectric layers 304 and conductive seed layers 306, to bond or stick to the glass core 302 without requiring additional intervening adhesive layers to be formed on the core. In some embodiments, however, additional intervening layers may still be included, whether for adhesion or other purposes. The process of forming surface-nitrided glass core substrate 300 is described in further detail in connection with FIGS. 4A-D.

FIGS. 4A-D illustrate cross-section views of a fully-nitrided glass core substrate 300 during various stages of fabrication. In the illustrated example, the nitrided glass core substrate 300 of FIG. 3 is fabricated using techniques for forming a fully nitrided glass core.

In FIG. 4A, a fully nitrided glass core 302 for the substrate is formed, or alternatively, a preformed fully nitrided glass core 302 is provided (e.g., from a glass or substrate manufacturer). In some embodiments, nitride glass core 302 may include one or more layers of nitrided glass, potentially along with one or more dielectric or adhesive layers bonding the glass layers together (not shown).

By way of comparison, while glass core 102 of FIG. 1 was surface nitridized, nitride glass core 302 is nitridized in its entirety. In some embodiments, for example, nitride glass core 302 may be manufactured using nitrided glass, rather than merely performing nitriding treatments on a glass core after it has been manufactured.

Similar to surface-nitrided glass core 102, fully-nitrided glass core 302 provides enhanced adhesion and enables subsequent layers (e.g., dielectric layers 304, conductive seed layers 306) to bond to the glass core with or without the presence of other intervening adhesive layers. As another advantage, fully-nitrided glass core 302 also provides a built-in nitride glass surface on the walls of the through holes 305, which are formed in FIG. 4C. In this manner, the nitrided glass walls of the through holes 305 provide enhanced adhesion for the conductive seed layers 306, which are formed in FIG. 4D.

Nitride glass core 302 may be manufactured using any suitable technique for forming nitrided glass. In some embodiments, for example, nitride glass core 302 may be formed using techniques for joining together nitrogen and glass materials. For example, pressurized and non-pressurized nitrogen-based heat treatments can be used to join together layers of nitrides and glass, such as thin plates of silicon nitride and oxynitride glass. Example techniques include glass slice, capillary infiltration, and glass-paste application.

In the glass slice technique, a thin plate of glass may be placed between two layers of silicon nitride or other suitable nitride materials. At high temperatures (e.g., between 1500° and 1600° C.), the joining glass softens and flows to uniformly cover the entire joint surface. Non-pressurized joining can be performed using the glass slice technique in a furnace with flowing nitrogen.

In the capillary infiltration technique, capillary forces may be used to draw molten glass into the joint between two silicon nitride layers. This technique may require temperatures of approximately 1800° C. to provide sufficiently low viscosities. In the absence of high nitrogen pressure, the joining glasses may vaporize and/or decompose at these high temperatures.

In the glass-paste technique, powdered glass may be applied in an organic binder to the joint surface. The binder material may subsequently be removed through a low-temperature calcination process. This process may also require temperatures of approximately 1800° C.

Any other suitable techniques also be used, either separately or in conjunction with the foregoing techniques.

In FIG. 4B, the surfaces of the substrate core are laminated with a dielectric film. As a result, dielectric layers 304 are formed above and below the nitrided glass core 302. The dielectric layers 304 may be formed using any suitable dielectric material or film, including any of the materials described above for dielectric layers 104.

In FIG. 4C, through holes 305 are formed through the substrate core (e.g., using techniques such as etching, laser drilling, imprinting, sand blasting, and so forth). The through holes 305 may be used to form vias in subsequent metallization steps (not shown).

In FIG. 4D, exposed surfaces of the substrate core are deposited or laminated with a conductive material. As a result, conductive layers 306 are formed on the top and bottom surfaces of the substrate core 300 (e.g., above and below the dielectric layers 304) and on the walls of the through holes 305. In some embodiments, the conductive layers 306 serve as seed layers for additional metal layers that are formed during subsequent metallization steps (not shown). For example, the conductive seed layers 306 may serve as an adhesive that bonds the subsequent metal layers to the dielectric layers 304 (and/or glass layers 302) on the substrate core 300. The conductive seed layers 306 may be formed using any suitable metal or other conductive material, including any of the materials described above for conductive seed layers 106.

At this point, the nitrided glass core substrate 300 may be complete. However, as noted above, subsequent metallization processing may be performed to pattern conductive traces or interconnects on the substrate 300 (e.g., using a combination of dielectric buildup layers, conductive layers, vias, conductive contacts, etc.).

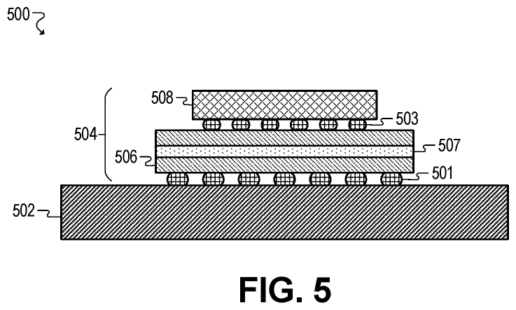

FIG. 5 illustrates a cross-section view of an electronic device 500 in accordance with certain embodiments. The electronic device 500 includes an integrated circuit package 504 electrically coupled to a board 502. The integrated circuit package 504 includes a package substrate 506 and an integrated circuit die 508 electrically coupled to the package substrate 506. In the illustrated embodiment, the package substrate 506 is a cored packaged substrate with a nitride glass core 507. In some embodiments, the nitride glass core 507 may be similar to the nitride glass core substrates described herein (e.g., nitride glass core substrates 100, 300). Further, in some embodiments, the board 502 may also be implemented with a nitride glass core (not shown).

In some embodiments, the board 502 may be a printed circuit board (PCB) or the like. The package substrate 506 is connected to the board 502 by conductive contacts 501, which may be referred to as second level interconnects (SLIs). In the illustrated embodiment, the interconnects 501 are shown as solder bumps, but it is to be appreciated that any interconnect architecture may be used (e.g., wire bonds, sockets, etc.).

The integrated circuit die 508 is electrically coupled to the package substrate 506 by conductive contacts 503, which may be referred to as first level interconnects (FLIs). The interconnects 503 may comprise solder, nickel, copper bumps, and/or the like, but it is to be appreciated that any interconnect architecture may be used.

The integrated circuit die 508 may include any suitable type of circuitry, including, but not limited to, processing circuitry, communication circuitry, and/or memory/storage circuitry. In some embodiments, for example, the integrated circuit die 508 may include a central processing unit (CPU), graphics processing unit (GPU), vision processing unit (VPU), microprocessor, microcontroller, field-programmable gate array (FPGA), application-specific integrated circuit (ASIC), input/output (I/O) controller, network interface controller (NIC), memory, and/or solid-state storage, among other examples.

The electronic device 500 may be any type of electronic device, including, but not limited to, a cell phone, a wearable device, a computer, a server, a camera, a video playback device, a video game console, a display device, a vehicle control unit, or an appliance.

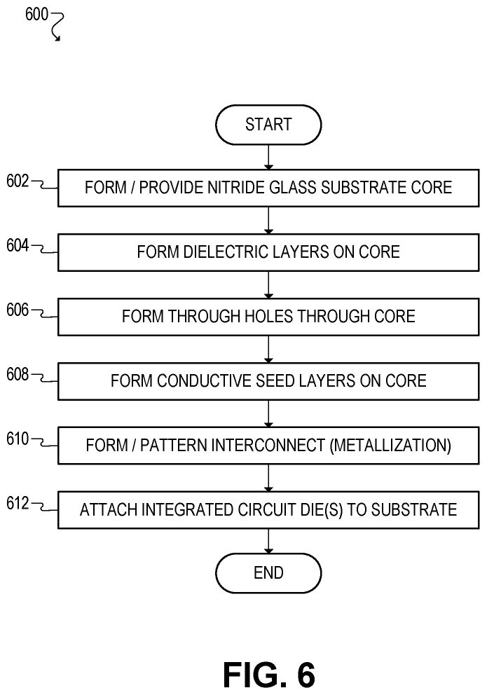

FIG. 6 illustrates a flowchart 600 for forming an integrated circuit (IC) package on a nitride glass core substrate in accordance with certain embodiments. In some embodiments, for example, flowchart 600 may be used to form an IC package on nitride glass core substrate 100, 300. It will be appreciated in light of this disclosure that flowchart 600 is only one example methodology for arriving at an IC package on the example nitride glass core substrates shown and described throughout this disclosure.

The steps of flowchart 600 may be performed using any suitable semiconductor fabrication techniques. For example, film deposition—such as depositing layers, filling portions of layers (e.g., removed portions), and filling via openings—may be performed using any suitable deposition techniques, including, for example, electroless deposition, chemical vapor deposition (CVD), metalorganic chemical vapor deposition (MOCVD), molecular beam epitaxy (MBE) atomic layer deposition (ALD), and/or physical vapor deposition (PVD). Moreover, patterning and removal—such as interconnect patterning, forming via openings, and shaping—may be performed using any suitable techniques, such as lithography-based patterning/masking and/or etching.

The flowchart begins at block 602 by forming or providing a nitride glass core for a package substrate. In some embodiments, the nitride glass core is formed by nitriding the surface of a glass core using surface nitridation techniques, such as performing gas and/or plasma nitriding treatments on the glass core. In this manner, the nitride glass core includes one or more middle layers or regions containing glass (e.g., without any nitrogen), along with top/bottom surface layers or regions containing nitride glass (e.g., nitrogen atoms in glass layer(s)).

Alternatively, in some embodiments, a fully nitrided glass core is formed by joining glass and nitrogen materials together (e.g., using the techniques described herein and/or known to those of ordinary skill in the art).

Further, in some embodiments, a pre-formed nitrided glass core may be provided (e.g., by a glass or substrate manufacturer).

The resulting nitride glass core includes one or more glass layers, at least one of which is a nitride glass layer (e.g., containing nitrogen and glass). For example, nitrogen atoms penetrate into and chemically bond with the glass layer(s), either at the surface of the glass core or throughout the entire glass core (depending on the particular technique used).

The flowchart then proceeds to block 604 to form dielectric layers on the surfaces of the nitride glass core (e.g., above and/or below the glass core layer(s)). In some embodiments, for example, the nitride glass core may be laminated with a dielectric film (e.g., ABF film).

The flowchart then proceeds to block 606 to form through holes through the nitride glass core.

The flowchart then proceeds to block 608 to form conductive seed layers on the surfaces of the nitride glass core (e.g., above and/or below the dielectric layers and/or on the walls of the through holes). In some embodiments, the conductive seed layers may be formed with titanium or copper.

The flowchart then proceeds to block 610 to form and pattern interconnect layers and structures (e.g., metallization processing) on the nitride glass core. In this manner, conductive traces/interconnects are formed on the nitride glass core, thus forming a completed package substrate.

For example, the through holes in the nitride glass core may be filled with metal to form through-hole vi as through the core. In addition, a series of alternating/interleaving dielectric (e.g., buildup, prepreg) and conductive layers may be formed above and/or below the core (e.g., with conductive layers separated by dielectric layers). Further, vias may be formed through the dielectric layers to form electrical connections between certain conductive layers (e.g., blind vias, buried vias, through hole vias). Finally, conductive contacts may be formed on the top and/or bottom surfaces of the substrate (e.g., solder balls/bumps, metal pads). In some embodiments, the metallization layers and structures may be formed using metals such as titanium, copper, tin, silver, gold, nickel, aluminum, and/or tungsten.

The dielectric/buildup layers, conductive layers, vias, and conductive contacts collectively serve as conductive traces or interconnects on the nitride glass core. The completed package substrate includes the nitride glass core (e.g., including the dielectric/conductive seed layers) and the various interconnect layers and structures (e.g., dielectric/buildup layers, conductive layers, vias, surface contacts).

The flowchart then proceeds to block 612 to attach one or more integrated circuit (IC) dies to the completed package substrate. For example, the package substrate and IC die(s) may be assembled such that the conductive contacts on the IC die(s) are electrically coupled to the conductive contacts on the surface of the package substrate. The completed IC package may subsequently be attached to a printed circuit board or another integrated circuit substrate, package, or device.

At this point, the flowchart may be complete. In some embodiments, however, the flowchart may restart and/or certain blocks may be repeated. For example, in some embodiments, the flowchart may restart at block 602 to form another integrated circuit package on a nitride glass core substrate with the same or similar design.

### Example Integrated Circuit Embodiments

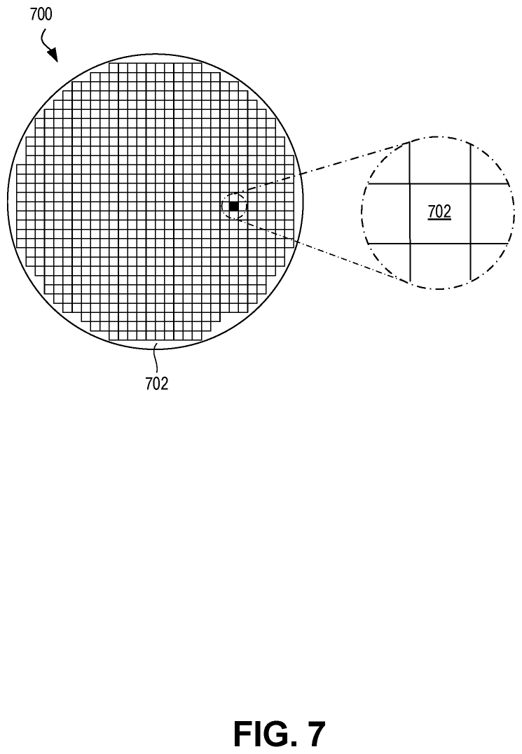

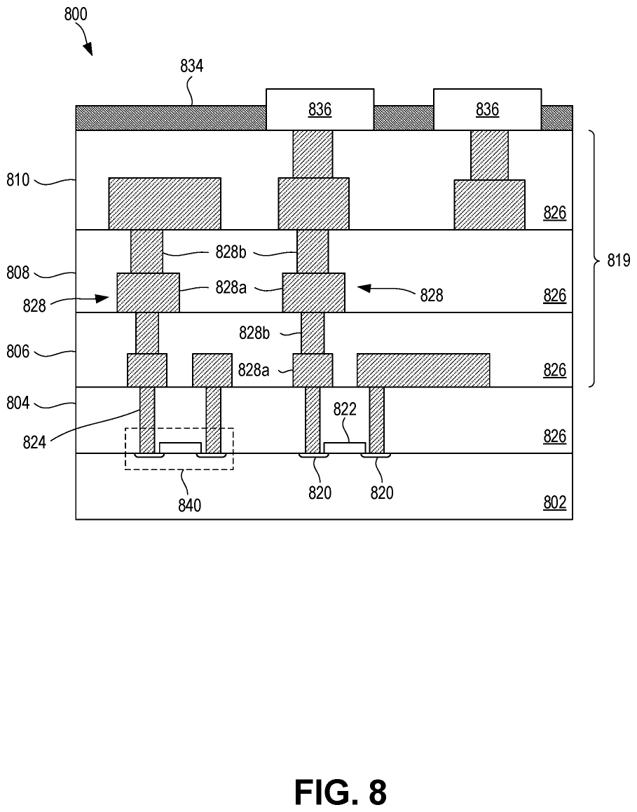

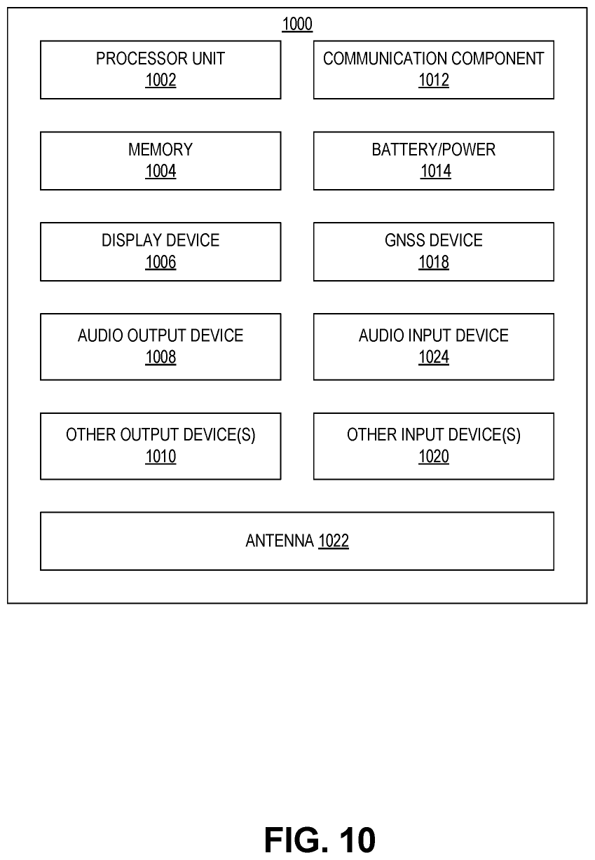

FIG. 7 is a top view of a wafer 700 and dies 702 that may be included in any of the embodiments disclosed herein. The wafer 700 may be composed of semiconductor material and may include one or more dies 702 having integrated circuit structures formed on a surface of the wafer 700. The individual dies 702 may be a repeating unit of an integrated circuit product that includes any suitable integrated circuit. After the fabrication of the semiconductor product is complete, the wafer 700 may undergo a singulation process in which the dies 702 are separated from one another to provide discrete “chips” of the integrated circuit product. The die 702 may be any of the dies disclosed herein. The die 702 may include one or more transistors (e.g., some of the transistors 840 of FIG. 8, discussed below), supporting circuitry to route electrical signals to the transistors, passive components (e.g., signal traces, resistors, capacitors, or inductors), and/or any other integrated circuit components. In some embodiments, the wafer 700 or the die 702 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 702. For example, a memory array formed by multiple memory devices may be formed on a same die 702 as a processor unit (e.g., the processor unit 1002 of FIG. 10) or other logic that is configured to store information in the memory devices or execute instructions stored in the memory array. Various ones of the microelectronic assemblies disclosed herein may be manufactured using a die-to-wafer assembly technique in which some dies are attached to a wafer 700 that include others of the dies, and the wafer 700 is subsequently singulated.

FIG. 8 is a cross-sectional side view of an integrated circuit device 800 that may be included in any of the embodiments disclosed herein (e.g., in any of the dies). One or more of the integrated circuit devices 800 may be included in one or more dies 702 (FIG. 7). The integrated circuit device 800 may be formed on a die substrate 802 (e.g., the wafer 700 of FIG. 7) and may be included in a die (e.g., the die 702 of FIG. 7). The die substrate 802 may be a semiconductor substrate composed of semiconductor material systems including, for example, n-type or p-type materials systems (or a combination of both). The die substrate 802 may include, for example, a crystalline substrate formed using a bulk silicon or a silicon-on-insulator (SOI) substructure. In some embodiments, the die substrate 802 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 802. Although a few examples of materials from which the die substrate 802 may be formed are described here, any material that may serve as a foundation for an integrated circuit device 800 may be used. The die substrate 802 may be part of a singulated die (e.g., the dies 702 of FIG. 7) or a wafer (e.g., the wafer 700 of FIG. 7).

The integrated circuit device 800 may include one or more device layers 804 disposed on the die substrate 802. The device layer 804 may include features of one or more transistors 840 (e.g., metal oxide semiconductor field-effect transistors (MOSFETs)) formed on the die substrate 802. The transistors 840 may include, for example, one or more source and/or drain (S/D) regions 820, a gate 822 to control current flow between the S/D regions 820, and one or more S/D contacts 824 to route electrical signals to/from the S/D regions 820. The transistors 840 may include additional features not depicted for the sake of clarity, such as device isolation regions, gate contacts, and the like. The transistors 840 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 8, a transistor 840 may include a gate 822 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 840 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 840 along the source-channel-drain direction, the gate electrode may consist of a U-shaped structure that includes a bottom portion substantially parallel to the surface of the die substrate 802 and two sidewall portions that are substantially perpendicular to the top surface of the die substrate 802. In other embodiments, at least one of the metal layers that form the gate electrode may simply be a planar layer that is substantially parallel to the top surface of the die substrate 802 and does not include sidewall portions substantially perpendicular to the top surface of the die substrate 802. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 820 may be formed within the die substrate 802 adjacent to the gate 822 of individual transistors 840. The S/D regions 820 may be formed using an implantation/diffusion process or an etching/deposition process, for example. In the former process, dopants such as boron, aluminum, antimony, phosphorous, or arsenic may be ion-implanted into the die substrate 802 to form the S/D regions 820. An annealing process that activates the dopants and causes them to diffuse farther into the die substrate 802 may follow the ion-implantation process. In the latter process, the die substrate 802 may first be etched to form recesses at the locations of the S/D regions 820. An epitaxial deposition process may then be carried out to fill the recesses with material that is used to fabricate the S/D regions 820. In some implementations, the S/D regions 820 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 820 may be formed using one or more alternate semiconductor materials such as germanium or a group III-V material or alloy. In further embodiments, one or more layers of metal and/or metal alloys may be used to form the S/D regions 820.

Electrical signals, such as power and/or input/output (I/O) signals, may be routed to and/or from the devices (e.g., transistors 840) of the device layer 804 through one or more interconnect layers disposed on the device layer 804 (illustrated in FIG. 8 as interconnect layers 806-810). For example, electrically conductive features of the device layer 804 (e.g., the gate 822 and the S/D contacts 824) may be electrically coupled with the interconnect structures 828 of the interconnect layers 806-810. The one or more interconnect layers 806-810 may form a metallization stack (also referred to as an “ILD stack”) 819 of the integrated circuit device 800.

The interconnect structures 828 may be arranged within the interconnect layers 806-810 to route electrical signals according to a wide variety of designs; in particular, the arrangement is not limited to the particular configuration of interconnect structures 828 depicted in FIG. 8. Although a particular number of interconnect layers 806-810 is depicted in FIG. 8, embodiments of the present disclosure include integrated circuit devices having more or fewer interconnect layers than depicted.

In some embodiments, the interconnect structures 828 may include lines 828a and/or vias 828b filled with an electrically conductive material such as a metal. The lines 828a may be arranged to route electrical signals in a direction of a plane that is substantially parallel with a surface of the die substrate 802 upon which the device layer 804 is formed. For example, the lines 828a may route electrical signals in a direction in and out of the page and/or in a direction across the page from the perspective of FIG. 8. The vias 828b may be arranged to route electrical signals in a direction of a plane that is substantially perpendicular to the surface of the die substrate 802 upon which the device layer 804 is formed. In some embodiments, the vias 828b may electrically couple lines 828a of different interconnect layers 806-810 together.

The interconnect layers 806-810 may include a dielectric material 826 disposed between the interconnect structures 828, as shown in FIG. 8. In some embodiments, dielectric material 826 disposed between the interconnect structures 828 in different ones of the interconnect layers 806-810 may have different compositions; in other embodiments, the composition of the dielectric material 826 between different interconnect layers 806-810 may be the same. The device layer 804 may include a dielectric material 826 disposed between the transistors 840 and a bottom layer of the metallization stack as well. The dielectric material 826 included in the device layer 804 may have a different composition than the dielectric material 826 included in the interconnect layers 806-810; in other embodiments, the composition of the dielectric material 826 in the device layer 804 may be the same as a dielectric material 826 included in any one of the interconnect layers 806-810.

A first interconnect layer 806 (referred to as Metal 1 or “M1”) may be formed directly on the device layer 804. In some embodiments, the first interconnect layer 806 may include lines 828a and/or vias 828b, as shown. The lines 828a of the first interconnect layer 806 may be coupled with contacts (e.g., the S/D contacts 824) of the device layer 804. The vias 828b of the first interconnect layer 806 may be coupled with the lines 828a of a second interconnect layer 808.

The second interconnect layer 808 (referred to as Metal 2 or “M2”) may be formed directly on the first interconnect layer 806. In some embodiments, the second interconnect layer 808 may include via 828b to couple the lines 828 of the second interconnect layer 808 with the lines 828a of a third interconnect layer 810. Although the lines 828a and the vias 828b are structurally delineated with a line within individual interconnect layers for the sake of clarity, the lines 828a and the vias 828b may be structurally and/or materially contiguous (e.g., simultaneously filled during a dual-damascene process) in some embodiments.

The third interconnect layer 810 (referred to as Metal 3 or “M3”) (and additional interconnect layers, as desired) may be formed in succession on the second interconnect layer 808 according to similar techniques and configurations described in connection with the second interconnect layer 808 or the first interconnect layer 806. In some embodiments, the interconnect layers that are “higher up” in the metallization stack 819 in the integrated circuit device 800 (i.e., farther away from the device layer 804) may be thicker that the interconnect layers that are lower in the metallization stack 819, with lines 828a and vias 828b in the higher interconnect layers being thicker than those in the lower interconnect layers.

The integrated circuit device 800 may include a solder resist material 834 (e.g., polyimide or similar material) and one or more conductive contacts 836 formed on the interconnect layers 806-810. In FIG. 8, the conductive contacts 836 are illustrated as taking the form of bond pads. The conductive contacts 836 may be electrically coupled with the interconnect structures 828 and configured to route the electrical signals of the transistor(s) 840 to external devices. For example, solder bonds may be formed on the one or more conductive contacts 836 to mechanically and/or electrically couple an integrated circuit die including the integrated circuit device 800 with another component (e.g., a printed circuit board). The integrated circuit device 800 may include additional or alternate structures to route the electrical signals from the interconnect layers 806-810; for example, the conductive contacts 836 may include other analogous features (e.g., posts) that route the electrical signals to external components. The conductive contacts 836 may serve as any of the conductive contacts described throughout this disclosure.

In some embodiments in which the integrated circuit device 800 is a double-sided die, the integrated circuit device 800 may include another metallization stack (not shown) on the opposite side of the device layer(s) 804. This metallization stack may include multiple interconnect layers as discussed above with reference to the interconnect layers 806-810, to provide conductive pathways (e.g., including conductive lines and vias) between the device layer(s) 804 and additional conductive contacts (not shown) on the opposite side of the integrated circuit device 800 from the conductive contacts 836. These additional conductive contacts may serve as any of the conductive contacts described throughout this disclosure.

In other embodiments in which the integrated circuit device 800 is a double-sided die, the integrated circuit device 800 may include one or more through silicon vias (TSVs) through the die substrate 802; these TSVs may make contact with the device layer(s) 804, and may provide conductive pathways between the device layer(s) 804 and additional conductive contacts (not shown) on the opposite side of the integrated circuit device 800 from the conductive contacts 836. These additional conductive contacts may serve as any of the conductive contacts described throughout this disclosure. In some embodiments, TSVs extending through the substrate can be used for routing power and ground signals from conductive contacts on the opposite side of the integrated circuit device 800 from the conductive contacts 836 to the transistors 840 and any other components integrated into the die 800, and the metallization stack 819 can be used to route I/O signals from the conductive contacts 836 to transistors 840 and any other components integrated into the die 800.

Multiple integrated circuit devices 800 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

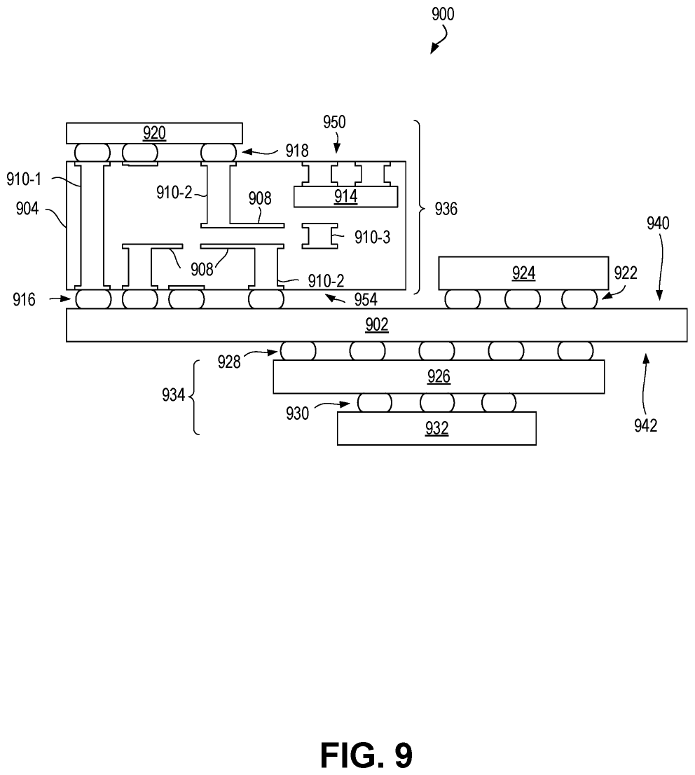

FIG. 9 is a cross-sectional side view of an integrated circuit device assembly 900 that may include any of the embodiments disclosed herein. For example, any suitable component of integrated circuit device assembly 900 may include one or more of the nitride glass core substrates 100, 300 disclosed herein. In some embodiments, the integrated circuit device assembly 900 may be a microelectronic assembly. The integrated circuit device assembly 900 includes a number of components disposed on a circuit board 902 (which may be a motherboard, system board, mainboard, etc.). The integrated circuit device assembly 900 includes components disposed on a first face 940 of the circuit board 902 and an opposing second face 942 of the circuit board 902; generally, components may be disposed on one or both faces 940 and 942. Any of the integrated circuit components discussed below with reference to the integrated circuit device assembly 900 may take the form of any suitable ones of the embodiments of the microelectronic assemblies 100 disclosed herein.

In some embodiments, the circuit board 902 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 902. In other embodiments, the circuit board 902 may be a non-PCB substrate. The integrated circuit device assembly 900 illustrated in FIG. 9 includes a package-on-interposer structure 936 coupled to the first face 940 of the circuit board 902 by coupling components 916. The coupling components 916 may electrically and mechanically couple the package-on-interposer structure 936 to the circuit board 902, and may include solder balls (as shown in FIG. 9), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 916 may serve as the coupling components illustrated or described for any of the substrate assembly or substrate assembly components described herein, as appropriate.

The package-on-interposer structure 936 may include an integrated circuit component 920 coupled to an interposer 904 by coupling components 918. The coupling components 918 may take any suitable form for the application, such as the forms discussed above with reference to the coupling components 916. Although a single integrated circuit component 920 is shown in FIG. 9, multiple integrated circuit components may be coupled to the interposer 904; indeed, additional interposers may be coupled to the interposer 904. The interposer 904 may provide an intervening substrate used to bridge the circuit board 902 and the integrated circuit component 920.

The integrated circuit component 920 may be a packaged or unpacked integrated circuit product that includes one or more integrated circuit dies (e.g., the die 702 of FIG. 7, the integrated circuit device 800 of FIG. 8) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 920, a single monolithic integrated circuit die comprises solder bumps attached to contacts on the die. The solder bumps allow the die to be directly attached to the interposer 904. The integrated circuit component 920 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 920 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 920 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 920 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 904 may spread connections to a wider pitch or reroute a connection to a different connection. For example, the interposer 904 may couple the integrated circuit component 920 to a set of ball grid array (BGA) conductive contacts of the coupling components 916 for coupling to the circuit board 902. In the embodiment illustrated in FIG. 9, the integrated circuit component 920 and the circuit board 902 are attached to opposing sides of the interposer 904; in other embodiments, the integrated circuit component 920 and the circuit board 902 may be attached to a same side of the interposer 904. In some embodiments, three or more components may be interconnected by way of the interposer 904.

In some embodiments, the interposer 904 may be formed as a PCB, including multiple metal layers separated from one another by layers of dielectric material and interconnected by electrically conductive vias. In some embodiments, the interposer 904 may be formed of an epoxy resin, a fiberglass-reinforced epoxy resin, an epoxy resin with inorganic fillers, a ceramic material, or a polymer material such as polyimide. In some embodiments, the interposer 904 may be formed of alternate rigid or flexible materials that may include the same materials described above for use in a semiconductor substrate, such as silicon, germanium, and other group III-V and group IV materials. The interposer 904 may include metal interconnects 908 and vias 910, including but not limited to through hole vias 910-1 (that extend from a first face 950 of the interposer 904 to a second face 954 of the interposer 904), blind vias 910-2 (that extend from the first or second faces 950 or 954 of the interposer 904 to an internal metal layer), and buried vias 910-3 (that connect internal metal layers).

In some embodiments, the interposer 904 can comprise a silicon interposer. Through silicon vias (TSV) extending through the silicon interposer can connect connections on a first face of a silicon interposer to an opposing second face of the silicon interposer. In some embodiments, an interposer 904 comprising a silicon interposer can further comprise one or more routing layers to route connections on a first face of the interposer 904 to an opposing second face of the interposer 904.

The interposer 904 may further include embedded devices 914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 904. The package-on-interposer structure 936 may take the form of any of the package-on-interposer structures known in the art. In embodiments where the interposer is a non-printed circuit board

The integrated circuit device assembly 900 may include an integrated circuit component 924 coupled to the first face 940 of the circuit board 902 by coupling components 922. The coupling components 922 may take the form of any of the embodiments discussed above with reference to the coupling components 916, and the integrated circuit component 924 may take the form of any of the embodiments discussed above with reference to the integrated circuit component 920.

The integrated circuit device assembly 900 illustrated in FIG. 9 includes a package-on-package structure 934 coupled to the second face 942 of the circuit board 902 by coupling components 928. The package-on-package structure 934 may include an integrated circuit component 926 and an integrated circuit component 932 coupled together by coupling components 930 such that the integrated circuit component 926 is disposed between the circuit board 902 and the integrated circuit component 932. The coupling components 928 and 930 may take the form of any of the embodiments of the coupling components 916 discussed above, and the integrated circuit components 926 and 932 may take the form of any of the embodiments of the integrated circuit component 920 discussed above. The package-on-package structure 934 may be configured in accordance with any of the package-on-package structures known in the art.

FIG. 10 is a block diagram of an example electrical device 1000 that may include one or more of the embodiments disclosed herein. For example, any suitable component(s) of the electrical device 1000 may include one or more of the nitride glass core substrates 100, 300, integrated circuit device assemblies 900, integrated circuit components 920, integrated circuit devices 800, or integrated circuit dies 702 disclosed herein. A number of components are illustrated in FIG. 10 as included in the electrical device 1000, but any one or more of these components may be omitted or duplicated, as suitable for the application. In some embodiments, some or all of the components included in the electrical device 1000 may be attached to one or more motherboards mainboards, or system boards. In some embodiments, one or more of these components are fabricated onto a single system-on-a-chip (SoC) die.

Additionally, in various embodiments, the electrical device 1000 may not include one or more of the components illustrated in FIG. 10, but the electrical device 1000 may include interface circuitry for coupling to the one or more components. For example, the electrical device 1000 may not include a display device 1006, but may include display device interface circuitry (e.g., a connector and driver circuitry) to which a display device 1006 may be coupled. In another set of examples, the electrical device 1000 may not include an audio input device 1024 or an audio output device 1008, but may include audio input or output device interface circuitry (e.g., connectors and supporting circuitry) to which an audio input device 1024 or audio output device 1008 may be coupled.

The electrical device 1000 may include one or more processor units 1002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1000 may include a memory 1004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1004 may include memory that is located on the same integrated circuit die as the processor unit 1002. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1000 can comprise one or more processor units 1002 that are heterogeneous or asymmetric to another processor unit 1002 in the electrical device 1000. There can be a variety of differences between the processing units 1002 in a system in terms of a spectrum of metrics of merit including architectural, microarchitectural, thermal, power consumption characteristics, and the like. These differences can effectively manifest themselves as asymmetry and heterogeneity among the processor units 1002 in the electrical device 1000.

In some embodiments, the electrical device 1000 may include a communication component 1012 (e.g., one or more communication components). For example, the communication component 1012 can manage wireless communications for the transfer of data to and from the electrical device 1000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1012 may operate in accordance with other wireless protocols in other embodiments. The electrical device 1000 may include an antenna 1022 to facilitate wireless communications and/or to receive other wireless communications (such as AM or FM radio transmissions).

In some embodiments, the communication component 1012 may manage wired communications, such as electrical, optical, or any other suitable communication protocols (e.g., IEEE 802.3 Ethernet standards). As noted above, the communication component 1012 may include multiple communication components. For instance, a first communication component 1012 may be dedicated to shorter-range wireless communications such as Wi-Fi or Bluetooth, and a second communication component 1012 may be dedicated to longer-range wireless communications such as global positioning system (GPS), EDGE, GPRS, CDMA, WiMAX, LTE, EV-DO, or others. In some embodiments, a first communication component 1012 may be dedicated to wireless communications, and a second communication component 1012 may be dedicated to wired communications.

The electrical device 1000 may include battery/power circuitry 1014. The battery/power circuitry 1014 may include one or more energy storage devices (e.g., batteries or capacitors) and/or circuitry for coupling components of the electrical device 1000 to an energy source separate from the electrical device 1000 (e.g., AC line power).

The electrical device 1000 may include a display device 1006 (or corresponding interface circuitry, as discussed above). The display device 1006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1000 may include an audio output device 1008 (or corresponding interface circuitry, as discussed above). The audio output device 1008 may include any embedded or wired or wirelessly connected external device that generates an audible indicator, such speakers, headsets, or earbuds.

The electrical device 1000 may include an audio input device 1024 (or corresponding interface circuitry, as discussed above). The audio input device 1024 may include any embedded or wired or wirelessly connected device that generates a signal representative of a sound, such as microphones, microphone arrays, or digital instruments (e.g., instruments having a musical instrument digital interface (MIDI) output). The electrical device 1000 may include a Global Navigation Satellite System (GNSS) device 1018 (or corresponding interface circuitry, as discussed above), such as a Global Positioning System (GPS) device. The GNSS device 1018 may be in communication with a satellite-based system and may determine a geolocation of the electrical device 1000 based on information received from one or more GNSS satellites, as known in the art.

The electrical device 1000 may include other output device(s) 1010 (or corresponding interface circuitry, as discussed above). Examples of the other output device(s) 1010 may include an audio codec, a video codec, a printer, a wired or wireless transmitter for providing information to other devices, or an additional storage device.

The electrical device 1000 may include other input device(s) 1020 (or corresponding interface circuitry, as discussed above). Examples of the other input device(s) 1020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a display device (e.g., monitor, television), a set-top box, an entertainment control unit, a video game console, a video playback device, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1000 may be any other electronic device that processes data. In some embodiments, the electrical device 1000 may comprise multiple discrete physical components. Given the range of devices that the electrical device 1000 can be manifested as in various embodiments, in some embodiments, the electrical device 1000 can be referred to as a computing device or a computing system.

### Example Embodiments

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes a substrate, comprising: one or more glass layers, wherein at least one of the glass layers comprises nitrogen; and a plurality of dielectric layers, wherein at least one of the dielectric layers is above the one or more glass layers and at least one of the dielectric layers is below the one or more glass layers.

Example 2 includes the substrate of Example 1, wherein the one or more glass layers comprise: a first glass layer, wherein the first glass layer does not comprise nitrogen; and a plurality of second glass layers, wherein the plurality of second glass layers comprise nitrogen, wherein at least one of the second glass layers is above the first glass layer and at least one of the second glass layers is below the first glass layer.

Example 3 includes the substrate of Example 1, wherein at least one of the glass layers comprises a top glass region, a bottom glass region, and a middle glass region, wherein the top glass region and the bottom glass region comprise nitrogen, and wherein the middle glass region does not comprise nitrogen.

Example 4 includes the substrate of Example 1, wherein the one or more glass layers comprise a nitride glass layer, wherein the nitride glass layer comprises nitrogen atoms within glass.

Example 5 includes the substrate of Example 4, wherein the nitrogen atoms are at one or more surfaces of the nitride glass layer.

Example 6 includes the substrate of any of Examples 1-5, further comprising a plurality of conductive layers, wherein at least one of the conductive layers is above the plurality of dielectric layers and at least one of the conductive layers is below the plurality of dielectric layers.

Example 7 includes the substrate of Example 6, wherein the plurality of conductive layers comprise titanium or copper.

Example 8 includes the substrate of any of Examples 6-7, further comprising one or more through-hole vias through the substrate.

Example 9 includes an integrated circuit package, comprising: an integrated circuit die; and a package substrate electrically coupled to the integrated circuit die, the package substrate comprising: one or more glass layers, wherein at least one of the glass layers comprises nitrogen; a plurality of dielectric layers, wherein at least one of the dielectric layers is above the one or more glass layers and at least one of the dielectric layers is below the one or more glass layers; and one or more conductive traces through the package substrate.

Example 10 includes the integrated circuit package of Example 9, further comprising one or more conductive contacts on a surface of the package substrate.

Example 11 includes the integrated circuit package of any of Examples 9-10, wherein the one or more conductive traces comprise one or more through-hole vias through the package substrate.

Example 12 includes the integrated circuit package of any of Examples 9-11, wherein the one or more glass layers comprise: a first glass layer, wherein the first glass layer does not comprise nitrogen; and a plurality of second glass layers, wherein the plurality of second glass layers comprise nitrogen, wherein at least one of the second glass layers is above the first glass layer and at least one of the second glass layers is below the first glass layer.

Example 13 includes the integrated circuit package of any of Examples 9-11, wherein at least one of the glass layers comprises a top glass region, a bottom glass region, and a middle glass region, wherein the top glass region and the bottom glass region comprise nitrogen, and wherein the middle glass region does not comprise nitrogen.

Example 14 includes the integrated circuit package of any of Examples 9-11, wherein the one or more glass layers comprise a nitride glass layer, wherein the nitride glass layer comprises nitrogen atoms at one or more surfaces of the nitride glass layer.

Example 15 includes the integrated circuit package of any of Examples 9-14, further comprising a plurality of conductive layers, wherein at least one of the conductive layers is above the plurality of dielectric layers and at least one of the conductive layers is below the plurality of dielectric layers.

Example 16 includes an electronic device, comprising: a board; and an integrated circuit package coupled to the board, wherein the integrated circuit package comprises: an integrated circuit die; and a package substrate electrically coupled to the integrated circuit die, the package substrate comprising: one or more glass layers, wherein at least one of the glass layers comprises nitrogen; a plurality of dielectric layers, wherein at least one of the dielectric layers is above the one or more glass layers and at least one of the dielectric layers is below the one or more glass layers; and one or more conductive traces through the package substrate.

Example 17 includes the electronic device of Example 16, wherein the one or more glass layers comprise a nitride glass layer, wherein the nitride glass layer comprises nitrogen atoms at one or more surfaces of the nitride glass layer.

Example 18 includes the electronic device of any of Examples 16-17, wherein the integrated circuit die comprises processing circuitry, communication circuitry, or memory circuitry.

Example 19 includes the electronic device of any of Examples 16-18, wherein the electronic device is a cell phone, a wearable device, a computer, a server, a camera, a video playback device, a video game console, a display device, a vehicle control unit, or an appliance.

Example 20 includes a method of forming a substrate, comprising: forming a nitride glass core; forming a plurality of dielectric layers above and below the nitride glass core; and forming a plurality of conductive seed layers above and below the plurality of dielectric layers.

Example 21 includes the method of Example 20, wherein forming the nitride glass core comprises: providing a glass core; and nitriding a surface of the glass core.

Example 22 includes the method of Example 21, wherein nitriding the surface of the glass core comprises: performing a gas nitriding treatment on the glass core.

Example 23 includes the method of Example 21, wherein nitriding the surface of the glass core comprises: performing a plasma nitriding treatment on the glass core.

Example 24 includes the method of Example 20, wherein forming the nitride glass core comprises: joining a glass material with a nitrogen material.

Example 25 includes the method of any of Examples 20-24, further comprising: forming one or more through-hole vias through the nitride glass core.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features. Further, it should be understood that the various embodiments shown in the figures are illustrative representations and are not necessarily drawn to scale.

Moreover, the illustrations and/or descriptions of various embodiments may be simplified or approximated for ease of understanding, and as a result, they may not necessarily reflect the level of precision nor variation that may be present in actual embodiments. For example, while some figures generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for ease of understanding and may vary by some margin of error in actual embodiments (e.g., due to fabrication processes, etc.).

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

The terms “substantially,” “close,” “approximately,” “near,” and “about,” generally refer to being within +/−10% of a target value (unless otherwise specified). Similarly, terms describing spatial relationships, such as “perpendicular,” “orthogonal,” or “coplanar,” may refer to being substantially within the described spatial relationships (e.g., within +/−10 degrees of orthogonality).

Certain terminology may also be used in the foregoing description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

The terms “over”, “between”, “adjacent”, “to”, and “on” as used herein may refer to a relative position of one layer or component with respect to other layers or components. For example, one layer “over” or “on” another layer, “adjacent” to another layer, or bonded “to” another layer may be directly in contact with the other layer or may have one or more intervening layers. One layer “between” layers may be directly in contact with the layers or may have one or more intervening layers.

The meaning of “a,” “an,” and “the” include plural references. The meaning of “in” includes “in” and “on.”

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

The term “coreless” generally refers to a substrate of an integrated circuit package having no core. The lack of a core allows for higher-density package architectures, as the through-vias have relatively large dimensions and pitch compared to high-density interconnects.

The term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

The term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and carries the same meaning.

The term “solder bump” generally refers to a solder layer formed on a bond pad. The solder layer typically has a round shape, hence the term “solder bump”.

The term “substrate” generally refers to a planar platform comprising dielectric and/or metallization structures. The substrate may mechanically support and electrically couple one or more IC dies on a single platform, with encapsulation of the one or more IC dies by a moldable dielectric material. The substrate may include solder bumps (or other conductive contacts) as bonding interconnects on one or both sides. One side of the substrate, generally referred to as the “die side”, may include solder bumps for chip or die bonding. The opposite side of the substrate, generally referred to as the “land side”, may include solder bumps for bonding the package to a printed circuit board.

The term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

The terms “coupled” or “connected” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal.

1. A substrate, comprising:
one or more glass layers, wherein at least one of the glass layers comprises nitrogen; and
a plurality of dielectric layers, wherein at least one of the dielectric layers is above the one or more glass layers and at least one of the dielectric layers is below the one or more glass layers.

2. The substrate of claim 1, wherein the one or more glass layers comprise:
a first glass layer, wherein the first glass layer does not comprise nitrogen; and
a plurality of second glass layers, wherein the plurality of second glass layers comprise nitrogen, wherein at least one of the second glass layers is above the first glass layer and at least one of the second glass layers is below the first glass layer.

3. The substrate of claim 1, wherein at least one of the glass layers comprises a top glass region, a bottom glass region, and a middle glass region, wherein the top glass region and the bottom glass region comprise nitrogen, and wherein the middle glass region does not comprise nitrogen.

4. The substrate of claim 1, wherein the one or more glass layers comprise a nitride glass layer, wherein the nitride glass layer comprises nitrogen atoms within glass.

5. The substrate of claim 4, wherein the nitrogen atoms are at one or more surfaces of the nitride glass layer.

6. The substrate of claim 1, further comprising a plurality of conductive layers, wherein at least one of the conductive layers is above the plurality of dielectric layers and at least one of the conductive layers is below the plurality of dielectric layers.

7. The substrate of claim 6, wherein the plurality of conductive layers comprise titanium or copper.

8. The substrate of claim 6, further comprising one or more through-hole vias through the substrate.

9. An integrated circuit package, comprising:
an integrated circuit die; and
a package substrate electrically coupled to the integrated circuit die, the package substrate comprising:
one or more glass layers, wherein at least one of the glass layers comprises nitrogen;
a plurality of dielectric layers, wherein at least one of the dielectric layers is above the one or more glass layers and at least one of the dielectric layers is below the one or more glass layers; and
one or more conductive traces through the package substrate.

10. The integrated circuit package of claim 9, further comprising one or more conductive contacts on a surface of the package substrate.

11. The integrated circuit package of claim 9, wherein the one or more conductive traces comprise one or more through-hole vias through the package substrate.

12. The integrated circuit package of claim 9, wherein the one or more glass layers comprise:
a first glass layer, wherein the first glass layer does not comprise nitrogen; and
a plurality of second glass layers, wherein the plurality of second glass layers comprise nitrogen, wherein at least one of the second glass layers is above the first glass layer and at least one of the second glass layers is below the first glass layer.

13. The integrated circuit package of claim 9, wherein at least one of the glass layers comprises a top glass region, a bottom glass region, and a middle glass region, wherein the top glass region and the bottom glass region comprise nitrogen, and wherein the middle glass region does not comprise nitrogen.

14. The integrated circuit package of claim 9, wherein the one or more glass layers comprise a nitride glass layer, wherein the nitride glass layer comprises nitrogen atoms at one or more surfaces of the nitride glass layer.

15. The integrated circuit package of claim 9, further comprising a plurality of conductive layers, wherein at least one of the conductive layers is above the plurality of dielectric layers and at least one of the conductive layers is below the plurality of dielectric layers.

16. An electronic device, comprising:
a board; and
an integrated circuit package coupled to the board, wherein the integrated circuit package comprises:
an integrated circuit die; and
a package substrate electrically coupled to the integrated circuit die, the package substrate comprising:
one or more glass layers, wherein at least one of the glass layers comprises nitrogen;
a plurality of dielectric layers, wherein at least one of the dielectric layers is above the one or more glass layers and at least one of the dielectric layers is below the one or more glass layers; and
one or more conductive traces through the package substrate.

17. The electronic device of claim 16, wherein the one or more glass layers comprise a nitride glass layer, wherein the nitride glass layer comprises nitrogen atoms at one or more surfaces of the nitride glass layer.

18. The electronic device of claim 16, wherein the integrated circuit die comprises processing circuitry, communication circuitry, or memory circuitry.

19. The electronic device of claim 16, wherein the electronic device is a cell phone, a wearable device, a computer, a server, a camera, a video playback device, a video game console, a display device, a vehicle control unit, or an appliance.

20. A method of forming a substrate, comprising:
forming a nitride glass core;
forming a plurality of dielectric layers above and below the nitride glass core; and
forming a plurality of conductive seed layers above and below the plurality of dielectric layers.

21. The method of claim 20, wherein forming the nitride glass core comprises:
providing a glass core; and
nitriding a surface of the glass core.

22. The method of claim 21, wherein nitriding the surface of the glass core comprises:
performing a gas nitriding treatment on the glass core.

23. The method of claim 21, wherein nitriding the surface of the glass core comprises:
performing a plasma nitriding treatment on the glass core.

24. The method of claim 20, wherein forming the nitride glass core comprises:
joining a glass material with a nitrogen material.

25. The method of claim 20, further comprising:
forming one or more through-hole vias through the nitride glass core.
